(19) United States
(12) Patent Application Publication
(10) Pub. No.: US 2025/0067518 A1
(43) Pub. Date: Feb. 27, 2025

(54) HEAT EXCHANGER

(71) Applicant: NIFCO INC., Yokosuka-shi, Kanagawa (JP)

(72) Inventor: Shunsuke OKABAYASHI, Yokosuka-shi, Kanagawa (JP)

(21) Appl. No.: 18/726,773

(22) PCT Filed: Dec. 23, 2022
(86) PCT No.: PCT/JP2022/047681

§ 371 Date: Jul. 3, 2024

(30) Foreign Application Priority Data
Jan. 28, 2022 (JP) 2022-012351

(51) Int. Cl. F28D 9/00

(52) U.S. Cl. CPC F28D 9/0093

(57) ABSTRACT

A heat exchanger includes a base part including a first base channel and a second base channel along which a medium flows in a first direction and a plurality of first heat exchanging bodies connected to the base part and aligned in the first direction, each of the first heat exchanging bodies being between two target members and including a first channel through which the medium circulates in a second direction intersecting the first direction. The first heat exchanging bodies each include a front portion and a back portion, a first outer edge joint portion joining inner surfaces of a first film along outer edges of the front portion and the back portion, and a first section joint portion joining inner surfaces of the first film so as to divide the first channel into a first forward channel and a first return channel. The base part includes the first film.

### RELATED APPLICATIONS

The present application is National Phase of International Application No. PCT/JP2022/047681 filed Dec. 23, 2022, and claims priority from Japanese Application No. 2022-012351, filed Jan. 28, 2022.

### FIELD

The present invention relates to a heat exchanger.

### BACKGROUND

An apparatus with large capacity, such as an energy storage unit for photovoltaic power generation or wind power generation and a storage battery of an electric vehicle or a hybrid vehicle, includes a plurality of devices. The devices are, for example, battery cells. When the apparatus is used, heat is generated in the devices, increasing the temperature of the devices. The apparatus preferably includes a heat exchanger for cooling the devices.

For example, Patent Literature 1 discloses a heat exchanger including a plurality of heat exchanging bodies corresponding to respective devices. Each of the heat exchanging bodies is positioned between two devices. Thus, each of the devices can be cooled uniformly. This can protect an apparatus, such as an energy storage unit and a storage battery. For example, decrease in performance and safety of the apparatus due to heat can be restrained. Furthermore, each of the heat exchanging bodies is composed of a flexible film. Thus, weight reduction is achieved in comparison with a case where heat exchanging bodies are composed of metal.

### CITATION LIST

### Patent Literature

Patent Literature 1: Japanese Patent Application Laid-open No. 2021-27020

### SUMMARY

### Technical Problem

Each of the heat exchanging bodies of Patent Literature 1 includes an inlet for introducing a medium into the heat exchanging body, an outlet for discharging the medium from the heat exchanging body, and joint pipes attached to the inlet and the outlet. Two adjacent heat exchanging bodies are connected via piping connected to the joint pipes. Thus, the apparatus manufacturing processes include a large number of processes, such as a process of attaching the joint pipes and a process of connecting the piping. Furthermore, the number of components composing the apparatus is large. This results in increase in cost of the apparatus manufacturing processes.

An object of the present invention is to provide a heat exchanger that can solve these problems.

### Solution to Problem

The present invention is a heat exchanger exchanging heat with a plurality of target members aligned in a first direction and including:
a base part including a first base channel and a second base channel along which a medium flows in the first direction; and
a plurality of first heat exchanging bodies connected to the base part and aligned in the first direction, each of the first heat exchanging bodies being positioned between two of the target members and including a first channel through which the medium circulates in a second direction intersecting the first direction, in which
the first heat exchanging bodies each include a front portion and a back portion configured by folding a first film, a first outer edge joint portion joining inner surfaces of the first film along outer edges of the front portion and the back portion, and a first section joint portion joining inner surfaces of the first film so as to divide the first channel into a first forward channel connected to the first base channel and a first return channel connected to the second base channel, and
the base part includes the first film.

In the heat exchanger according to the present invention, the base part may include an inlet portion positioned at a first end in the first direction and supplying the medium to the first base channel and an outlet portion positioned on a side opposite to the first end in the first direction and discharging the medium from the second base channel.

The heat exchanger according to the present invention may include a first reinforcing member inserted between the front portion and the back portion of the first heat exchanging body and surrounded by the first section joint portion.

The heat exchanger according to the present invention may include a reinforcing structure including a base reinforcing member positioned between the first base channel and the second base channel and a plurality of the first reinforcing members connected to the base reinforcing member and surrounded by the first section joint portions.

In the heat exchanger according to the present invention, the base part may include a second film including an inner surface facing the inner surface of the first film and a base section joint portion positioned between the first base channel and the second base channel and joining the inner surface of the first film to the inner surface of the second film.

In the heat exchanger according to the present invention, the second film may expand flat in a position where the first section joint portions are connected to the base section joint portion.

The heat exchanger according to the present invention may include a plurality of second heat exchanging bodies connected to the base part and aligned in the first direction, each of the second heat exchanging bodies including a second channel through which the medium circulates in the second direction. The second heat exchanging bodies may each include a front portion and a back portion configured by folding a second film, a second outer edge joint portion joining inner surfaces of the second film along outer edges of the front portion and the back portion, and a second section joint portion joining inner surfaces of the second film so as to divide the second channel into a second forward channel connected to the first base channel and a second return channel connected to the second base channel.

### Advantageous Effects of Invention

According to the present invention, the man-hours required to manufacture the heat exchanger can be reduced. Furthermore, the number of components composing the heat exchanger can be reduced.

### BRIEF DESCRIPTION OF DRAWINGS

FIG. 1 is a perspective view illustrating a heat exchanger according to a first embodiment.

FIG. 2 is a perspective view illustrating a power supply module according to the first embodiment.

FIG. 3 is a sectional view illustrating a case where the heat exchanger in FIG. 1 is cut along the line A-A.

FIG. 4 is a sectional view illustrating a case where the heat exchanger in FIG. 1 is cut along the line B-B.

FIG. 5 is a sectional view illustrating a case where the power supply module in FIG. 2 is cut along the line C-C.

FIG. 6 is a sectional view illustrating a case where the power supply module in FIG. 2 is cut along the line D-D.

FIG. 7 is a diagram illustrating one manufacturing process of the heat exchanger.

FIG. 8 is a diagram illustrating one manufacturing process of the heat exchanger.

FIG. 9 is a diagram illustrating one manufacturing process of the heat exchanger.

FIG. 10 is a diagram illustrating one manufacturing process of the heat exchanger.

FIG. 11 is a diagram illustrating one manufacturing process of the heat exchanger.

FIG. 12 is a diagram illustrating one manufacturing process of the heat exchanger.

FIG. 13 is a diagram illustrating one manufacturing process of the heat exchanger.

FIG. 14 is a diagram illustrating one manufacturing process of the heat exchanger.

FIG. 15 is a diagram illustrating a process of combining the heat exchanger and battery cells.

FIG. 16 is a perspective view illustrating a heat exchanger according to a first modification.

FIG. 17 is a perspective view illustrating a power supply module according to the first modification.

FIG. 18 is a sectional view illustrating a case where the heat exchanger in FIG. 17 is cut along the line E-E.

FIG. 19 is a sectional view illustrating a case where the heat exchanger in FIG. 17 is cut along the line F-F.

FIG. 20 is a perspective view illustrating an example spacer.

### DESCRIPTION OF EMBODIMENTS

An embodiment of the present invention will be described with reference to the drawings. In the drawings attached to this specification, for convenience of facilitation of understanding, the scale, the ratio of lengthwise and breadthwise dimensions, and the like are changed and exaggerated from actual ones as appropriate.

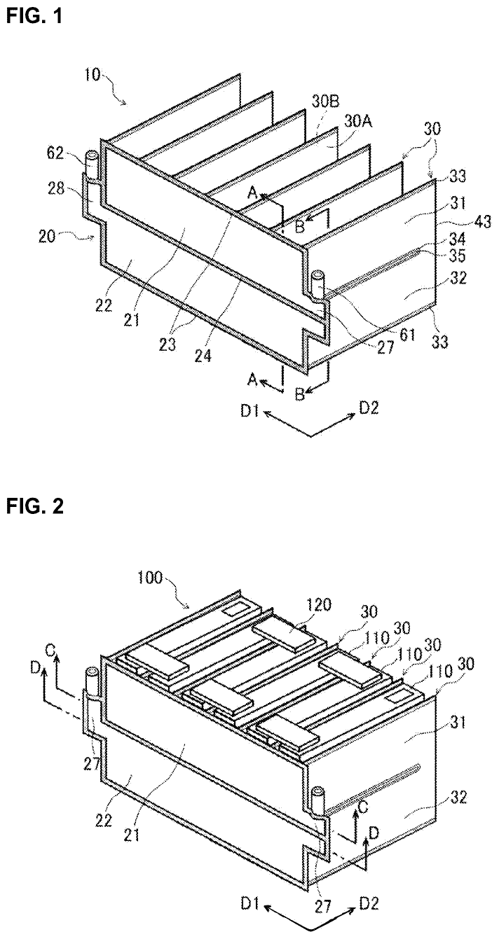

FIG. 1 is a perspective view illustrating an example of a heat exchanger 10. The heat exchanger 10 exchanges heat with a plurality of target members aligned in a first direction D1. The target members are, for example, battery cells. FIG. 2 is a perspective view illustrating an example of a power supply module 100 including the heat exchanger 10 and a plurality of battery cells 110. Two battery cells 110 adjacent to each other in the first direction D1 may be electrically connected by a connecting member 120.

The heat exchanger 10 will be described in detail. The heat exchanger 10 includes a base part 20 and a plurality of first heat exchanging bodies 30 connected to the base part 20.

The base part 20 will be described. As illustrated in FIG. 1, the base part 20 includes a first base channel 21 and a second base channel 22 along which a medium flows in the first direction D1. The first base channel 21 and the second base channel 22 both extend in the first direction D1. The medium before heat exchange with the battery cells 110 flows along the first base channel 21. That is, the first base channel 21 is positioned upstream of the battery cells 110. The medium after heat exchange with the battery cells 110 flows along the second base channel 22. That is, the second base channel 22 is positioned downstream of the battery cells 110. The medium is not particularly limited but is, for example, water.

The base part 20 may include an inlet portion 27 and an outlet portion 28. The inlet portion 27 is positioned at a first end of the base part 20 in the first direction D1. The inlet portion 27 introduces the medium into the first base channel 21. The outlet portion 28 is positioned at a second end of the base part 20 in the first direction D1. The second end is positioned on a side opposite to the first end in the first direction D1. The outlet portion 28 discharges the medium from the second base channel 22.

As illustrated in FIG. 1, an introducing member 61 may be attached to the inlet portion 27. Furthermore, a discharging member 62 may be attached to the outlet portion 28. The introducing member 61 and the discharging member 62 are, for example, tubular members. To the introducing member 61, piping for supplying the medium to the heat exchanger 10 is connected. To the discharging member 62, piping for collecting the medium discharged from the heat exchanger 10 is connected.

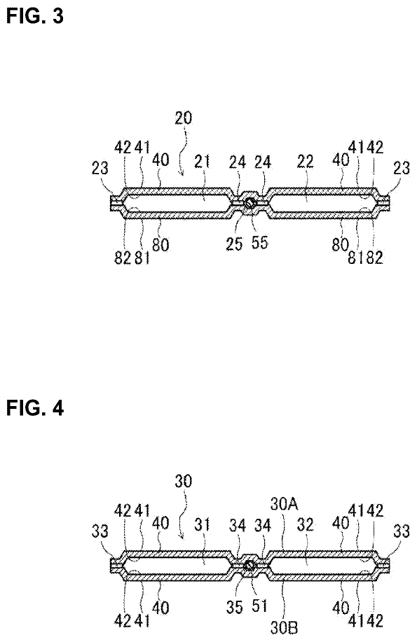

FIG. 3 is a sectional view illustrating a case where the heat exchanger 10 in FIG. 1 is cut along the line A-A. The base part 20 is composed of a single first film 40 and a single second film 80. The first film 40 includes an inner surface 42 and an outer surface 41 positioned on a side opposite to the inner surface 42. The second film 80 includes an inner surface 82 and an outer surface 81 positioned on a side opposite to the inner surface 82. The inner surface 82 of the second film 80 faces the inner surface 42 of the first film 40.

The base part 20 includes a base outer edge joint portion 23 and a base section joint portion 24. As illustrated in FIGS. 1 and 3, the base outer edge joint portion 23 is positioned at an outer edge of the base part 20. The base outer edge joint portion 23 joins the inner surface 42 of the first film 40 to the inner surface 82 of the second film 80. The medium flows through a space surrounded by the first film 40, the second film 80, and the base outer edge joint portion 23.

As illustrated in FIGS. 1 and 3, the base section joint portion 24 is positioned between the first base channel 21 and the second base channel 22. The base section joint portion 24 joins the inner surface 42 of the first film 40 to the inner surface 82 of the second film 80. The base section joint portion 24 divides a space inside the base part 20 into the first base channel 21 and the second base channel 22.

As illustrated in FIG. 3, a base non-joint portion 25 may be formed between the first base channel 21 and the second base channel 22. The base non-joint portion 25 is a portion where the inner surface 42 of the first film 40 is not joined to the inner surface 82 of the second film 80. The base non-joint portion 25 is surrounded by the base section joint portion 24. As illustrated in FIG. 3, a base reinforcing member 55 may be disposed in the base non-joint portion 25.

The base reinforcing member 55 is a bar member for enhancing rigidity of the base part 20. By attaching the base reinforcing member 55 to the base part 20, occurrence of deformation, such as a warp and bending, in the base part 20 can be restrained. The base reinforcing member 55 includes a member having higher rigidity than the first film 40 and the second film 80. For example, the thickness of the base reinforcing member 55 is greater than the thickness of the first film 40 and the thickness of the second film 80. The base reinforcing member 55 may be composed of resin, such as polypropylene.

Next, the first heat exchanging bodies 30 will be described. As illustrated in FIGS. 1 and 2, the first heat exchanging bodies 30 are aligned in the first direction D1. Each of the first heat exchanging bodies 30 expands in a second direction D2 intersecting the first direction D1. The second direction D2 may be orthogonal to the first direction D1. The first heat exchanging body 30 is positioned between two battery cells 110 adjacent to each other in the first direction D1.

The first heat exchanging body 30 includes a first channel through which the medium circulates in the second direction D2. The first channel includes a first forward channel 31 connected to the first base channel 21 and a first return channel 32 connected to the second base channel 22.

FIG. 3 is a sectional view illustrating a case where the heat exchanger 10 in FIG. 1 is cut along the line B-B. The first heat exchanging bodies 30 are composed of the single first film 40. The first film 40 composing the first heat exchanging bodies 30 is identical to the first film 40 of the base part 20. That is, the single first film 40 composes the first heat exchanging bodies 30 and a portion of the base part 20.

The first heat exchanging body 30 includes a front portion 30A, a back portion 30B, a first outer edge joint portion 33, and a first section joint portion 34. The front portion 30A and the back portion 30B are configured by folding the first film 40 along a folded portion 43 illustrated in FIG. 1.

As illustrated in FIGS. 1 and 4, the first outer edge joint portion 33 joins the inner surfaces 42 of the first film 40 along outer edges of the front portion 30A and the back portion 30B. The first outer edge joint portion 33 is connected to the base outer edge joint portion 23 of the base part 20. The medium flows through a space surrounded by the first film 40 composing the front portion 30A, the first film 40 composing the back portion 30B, the folded portion 43, and the first outer edge joint portion 33.

As illustrated in FIG. 1, the first section joint portion 34 extends from the base part 20 toward the folded portion 43 in the second direction D2. The first section joint portion 34 is connected to the base section joint portion 24 of the base part 20. The first section joint portion 34 joins the inner surface 42 of the first film 40 composing the front portion 30A to the inner surface 42 of the first film 40 composing the back portion 30B. The first section joint portion 34 divides the first channel of the first heat exchanging body 30 into the first forward channel 31 and the first return channel 32. The first section joint portion 34 is configured not to reach the folded portion 43. Thus, the first forward channel 31 and the first return channel 32 are linked in the vicinity of the folded portion 43.

As illustrated in FIG. 4, a first non-joint portion 35 may be formed between the first forward channel 31 and the first return channel 32. The first non-joint portion 35 is a portion where the inner surface 42 of the first film 40 composing the front portion 30A is not joined to the inner surface 42 of the first film 40 composing the back portion 30B. The first non-joint portion 35 is surrounded by the first section joint portion 34. As illustrated in FIG. 4, a first reinforcing member 51 may be disposed in the first non-joint portion 35. The first reinforcing member 51 is inserted between the front portion 30A and the back portion 30B.

The first reinforcing member 51 is a bar member for enhancing rigidity of the first heat exchanging body 30. By attaching the first reinforcing member 51 to the first heat exchanging body 30, occurrence of deformation, such as a warp and bending, in the first heat exchanging body 30 can be restrained. Similar to the base reinforcing member 55, the first reinforcing member 51 includes a member having higher rigidity than the first film 40. For example, the thickness of the first reinforcing member 51 is greater than the thickness of the first film 40. The material of the first reinforcing member 51 may be the same as the material of the base reinforcing member 55.

A plurality of the first reinforcing members 51 may be connected to the base reinforcing member 55. For example, the heat exchanger 10 may include a reinforcing structure 50 including the base reinforcing member 55 and the first reinforcing members 51 connected to the base reinforcing member 55.

As long as facing inner surfaces of a film can be joined to each other, there is no particular limitation on the method of forming the above-described joint portions, such as the base outer edge joint portion 23, the base section joint portion 24, the first outer edge joint portion 33, and the first section joint portion 34.

For example, the inner surfaces of the film may be melted by heating or the like and adhered to each other to form the joint portions. In this case, the inner surfaces of the film are composed of resin having thermal adhesiveness, such as a sealant layer.

Alternatively, the facing inner surfaces of the film may be adhered to each other using an adhesive or the like to form the joint portions.

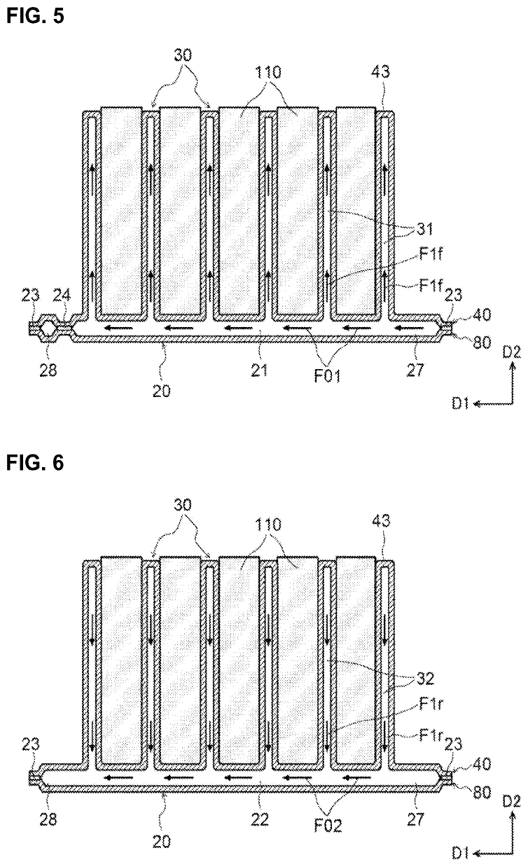

Next, operation of the heat exchanger 10 will be described. FIG. 5 is a sectional view illustrating a case where the power supply module 100 in FIG. 2 is cut along the line C-C. FIG. 6 is a sectional view illustrating a case where the power supply module 100 in FIG. 2 is cut along the line D-D.

As illustrated in FIG. 5, the medium introduced into the first base channel 21 of the base part 20 via the introducing member 61 and the inlet portion 27 flows toward the outlet portion 28 in the first direction D1. The medium flow along the first base channel 21 is also referred to as a first base flow F01.

As illustrated in FIG. 5, a plurality of the first forward channels 31 are connected to the first base channel 21. Thus, the first base flow F01 diverges and flows into each of the first forward channels 31. The medium flowing into the first forward channel 31 flows toward the folded portion 43 in the second direction D2. The medium flow along the first forward channel 31 is also referred to as a first forward flow F1f.

The first forward channel 31 is linked to the first return channel 32 in the vicinity of the folded portion 43. As illustrated in FIG. 6, the medium having reached the vicinity of the folded portion 43 flows along the first return channel 32 from the folded portion 43 toward the base part 20. The medium flow along the first return channel 32 is also referred to as a first return flow Fir.

When the medium flows into the first heat exchanging bodies 30, the first heat exchanging bodies 30 swell and come into contact with the battery cells 110. Thus, the medium exchanges heat with the battery cells 110 while flowing along the first forward channels 31 and the first return channels 32. This can cool the battery cells 110. The first heat exchanging bodies 30 are in contact with the respective battery cells 110, so that each of the battery cells 110 can be cooled more uniformly.

As illustrated in FIG. 6, a plurality of the first return channels 32 are connected to the second base channel 22. The medium in each of the first return channels 32 flows into the second base channel 22 and flows together. Then, the medium flows toward the outlet portion 28 in the first direction D1. The medium flow along the second base channel 22 is also referred to as a second base flow F02. The medium having reached the outlet portion 28 is discharged from the discharging member 62.

Next, a method of manufacturing the heat exchanger 10 and the power supply module 100 will be described.

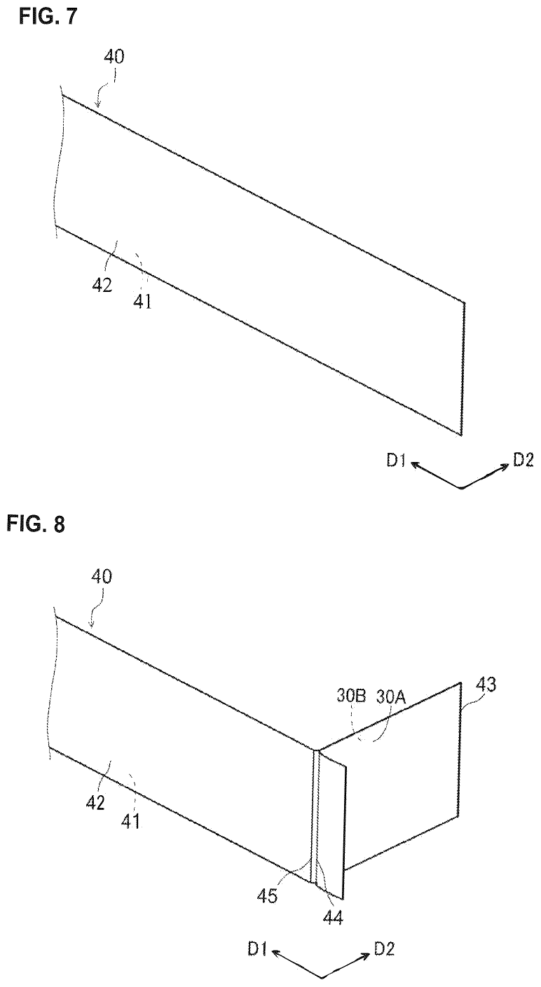

First, as illustrated in FIG. 7, the single first film 40 is prepared. Then, as illustrated in FIG. 8, a first folding process of folding a portion of the first film 40 along the folded portion 43 is performed. This forms the front portion 30A and the back portion 30B facing each other, in the first film 40. A first bent portion 44 may be formed at the base of the front portion 30A. A second bent portion 45 may be formed at the base of the back portion 30B.

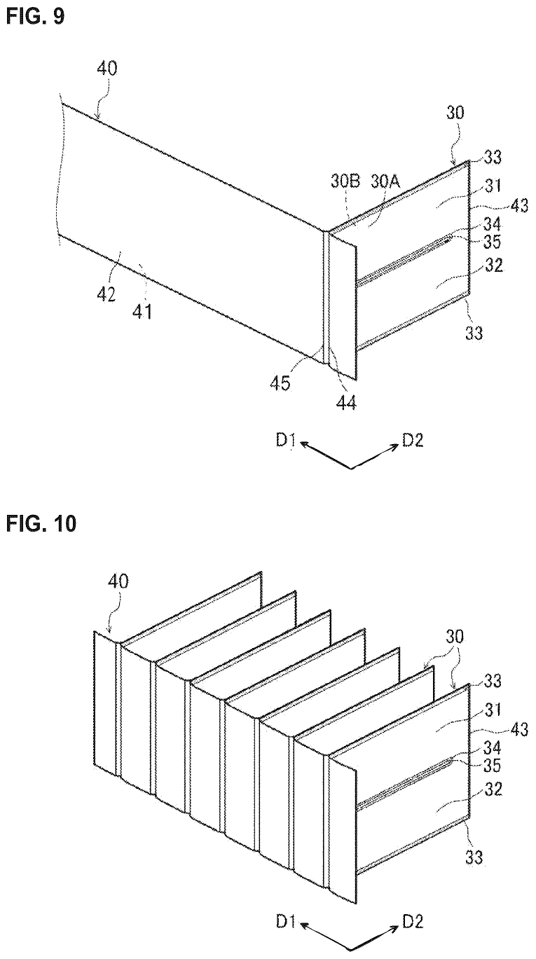

Then, a first joining process of partially joining the inner surface of the front portion 30A to the inner surface of the back portion 30B is performed. For example, sealant layers composing the inner surfaces are partially melted. As illustrated in FIG. 9, this forms the first outer edge joint portion 33 and the first section joint portion 34 between the front portion 30A and the back portion 30B. In this way, the first heat exchanging body 30 is formed.

The method of melting the sealant layers is not particularly limited.

For example, a die heated by a heater may be pressed against the first film 40 to melt the sealant layers. For example, the first film 40 may be partially irradiated with laser light to melt the sealant layers. In this case, the first film 40 may include a metal layer in contact with the sealant layers. The metal layer includes, for example, aluminum. By reflecting and diffusing the laser by the metal layer, the sealant layers can be melted.

The above-described first folding process and first joining process are performed repeatedly. As illustrated in FIG. 10, this forms the first heat exchanging bodies 30 aligned in the first direction D1.

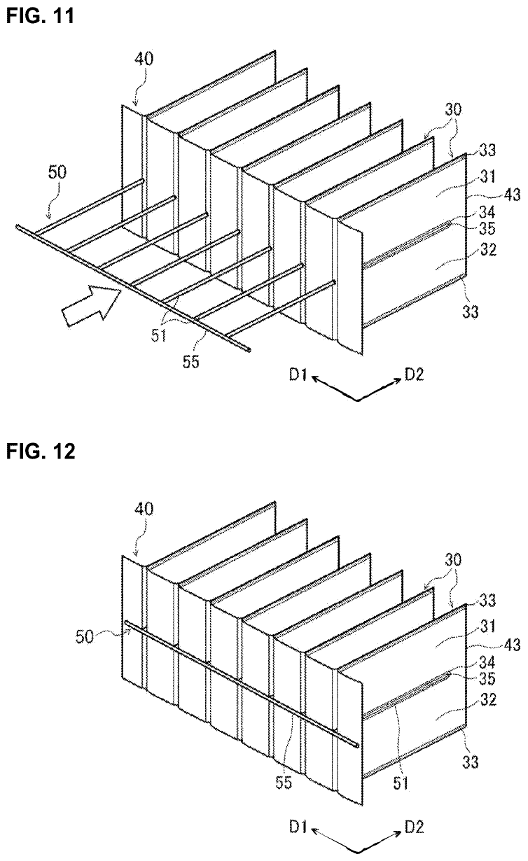

Then, as illustrated in FIG. 11, the reinforcing structure 50 is prepared. The reinforcing structure 50 includes the base reinforcing member 55 extending in the first direction D1 and the first reinforcing members 51 aligned in the first direction D1 and connected to the base reinforcing member 55. Then, as illustrated in FIGS. 11 and 12, the first reinforcing members 51 are inserted into the first non-joint portions 35 of the respective first heat exchanging bodies 30.

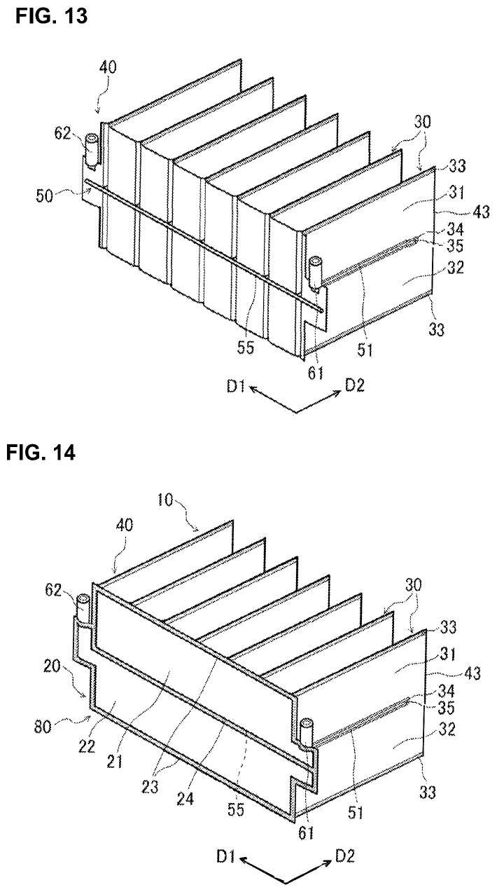

Then, as illustrated in FIG. 13, the introducing member 61 is joined to the first end of the first film 40 in the first direction D1. Furthermore, the discharging member 62 is joined to the second end of the first film 40 in the first direction D1.

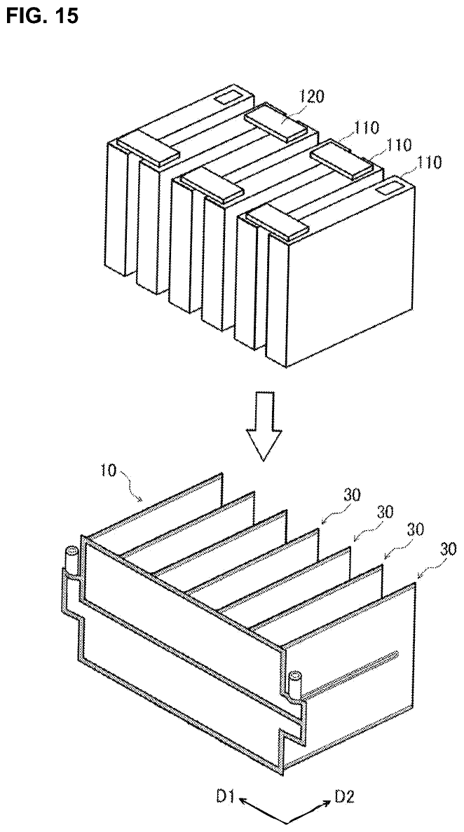

Then, as illustrated in FIG. 14, the second film 80 is overlaid on a portion, expanding in the first direction D1, of the first film 40. Then, a base joining process of partially joining the inner surface of the first film 40 to the inner surface of the second film 80 is performed. For example, sealant layers composing the inner surfaces are partially melted. As illustrated in FIG. 14, this forms the base outer edge joint portion 23 and the base section joint portion 24 between the first film 40 and the second film 80. The base section joint portion 24 is formed in such a manner that the base reinforcing member 55 is surrounded by the base section joint portion 24. In this way, the heat exchanger 10 including the base part 20 and the first heat exchanging bodies 30 is manufactured.

Then, as illustrated in FIG. 15, the heat exchanger 10 and the battery cells 110 are combined. This manufactures the power supply module 100 illustrated in FIG. 2.

According to this embodiment, the first heat exchanging bodies 30 are composed of the first film 40, so that the heat exchanger 10 is lighter than in a case where the first heat exchanging bodies 30 are composed of metal.

Furthermore, according to this embodiment, a portion of the base part 20 and the first heat exchanging bodies 30 are composed of the single first film 40. Thus, the first forward channels 31 of the first heat exchanging bodies 30 are naturally connected to the first base channel 21 of the base part 20. Similarly, the first return channels 32 of the first heat exchanging bodies 30 are naturally connected to the second base channel 22 of the base part 20. Thus, components, such as joint pipes, are unnecessary, which can reduce the number of components composing the heat exchanger 10. Furthermore, a process of attaching joint pipes and the like is unnecessary, which can reduce processes required to manufacture the heat exchanger 10. Thus, the manufacturing cost of the heat exchanger 10 can be reduced.

Furthermore, according to this embodiment, the first heat exchanging bodies 30 are composed of the first film 40, so that the first heat exchanging bodies 30 can bend and swell. Thus, the first heat exchanging bodies 30 readily come into close contact with the battery cells 110. This can increase heat exchange efficiency. Furthermore, even if there is an error in the dimensions or arrangement of the battery cells 110, deformation of the first heat exchanging bodies 30 can absorb the error. This can reduce the manufacturing cost of the power supply module 100.

Note that, when the power supply module 100 is not in use, the heat exchanger 10 is in any state. For example, the heat exchanger 10 may be stored or transported with the medium, air, and the like discharged from the inside of the heat exchanger 10.

Note that various modifications can be made to the above-described embodiment. Modifications will be described below with reference to the drawings as necessary. In the following description and the drawings used in the following description, parts that can be configured in the same way as in the above-described embodiment are denoted by the same reference signs used for the corresponding parts of the above-described embodiment, and overlapping description is omitted. Furthermore, when it is clear that the operation and effect acquired by the above-described embodiment can also be acquired by the modifications, its description may be omitted.

### First Modification

The above-described embodiment has provided an example in which the second film 80 composing the base part 20 expands flat. For example, an example in which the second film 80 expands flat in a position where the first section joint portions 34 are connected to the base section joint portion 24 has been provided. However, the shape of the second film 80 composing the base part 20 is not particularly limited. For example, similar to the first film 40, heat exchanging bodies may also be formed in the second film 80.

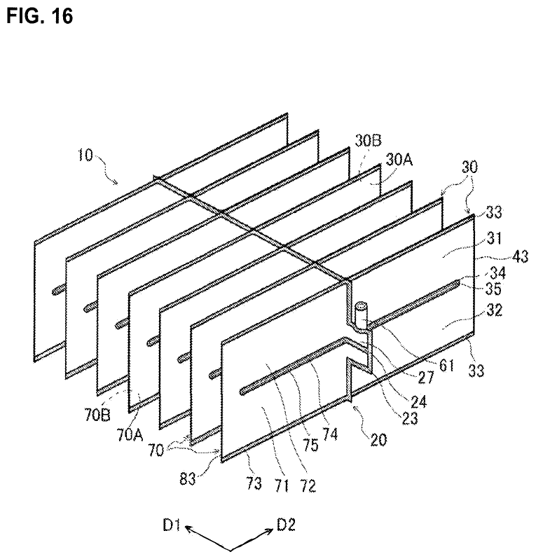

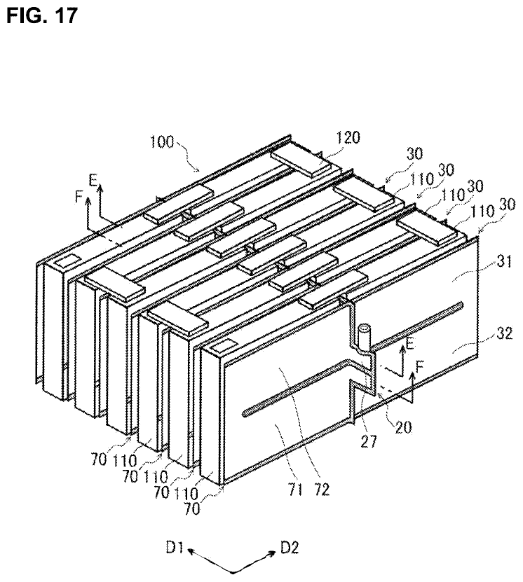

FIG. 16 is a perspective view illustrating a heat exchanger 10 according to this modification. The heat exchanger 10 includes a plurality of second heat exchanging bodies 70. Similar to the first heat exchanging bodies 30, the second heat exchanging bodies 70 are composed of a single second film 80. The second heat exchanging bodies 70 are connected to the base part 20 on a side opposite to a side having the first heat exchanging bodies 30.

FIG. 17 is a perspective view illustrating a power supply module 100 including the heat exchanger 10 in FIG. 16 and a plurality of battery cells 110. The second heat exchanging bodies 70 are aligned in the first direction D1. Each of the second heat exchanging bodies 70 expands in the second direction D2. The second heat exchanging body 70 is positioned between two battery cells 110 adjacent to each other in the first direction D1.

The second heat exchanging body 70 includes a second channel through which the medium circulates in the second direction D2. The second channel includes a second forward channel 71 connected to the first base channel 21 and a second return channel 72 connected to the second base channel 22.

The second heat exchanging body 70 includes a front portion 70A, a back portion 70B, a second outer edge joint portion 73, and a second section joint portion 74. The front portion 70A and the back portion 70B are configured by folding the second film 80 along a folded portion 83 illustrated in FIG. 16.

As illustrated in FIG. 16, the second outer edge joint portion 73 joins the inner surfaces of the second film 80 along outer edges of the front portion 70A and the back portion 70B. The second outer edge joint portion 73 is connected to the base outer edge joint portion 23 of the base part 20. The medium flows through a space surrounded by the second film 80 composing the front portion 70A, the second film 80 composing the back portion 70B, the folded portion 83, and the second outer edge joint portion 73.

As illustrated in FIG. 16, the second section joint portion 74 divides the second channel of the second heat exchanging body 70 into the second forward channel 71 and the second return channel 72. The second section joint portion 74 is configured not to reach the folded portion 83. Thus, the second forward channel 71 and the second return channel 72 are linked in the vicinity of the folded portion 83. The second section joint portion 74 is connected to the base section joint portion 24 of the base part 20.

A second non-joint portion 75 may be formed between the second forward channel 71 and the second return channel 72. The second non-joint portion 75 is surrounded by the second section joint portion 74. A second reinforcing member may be disposed in the second non-joint portion 75. Similar to the first reinforcing member 51, the second reinforcing member is a bar member for enhancing rigidity of the second heat exchanging body 70. Similar to the first reinforcing member 51, a plurality of the second reinforcing members may be connected to the base reinforcing member 55.

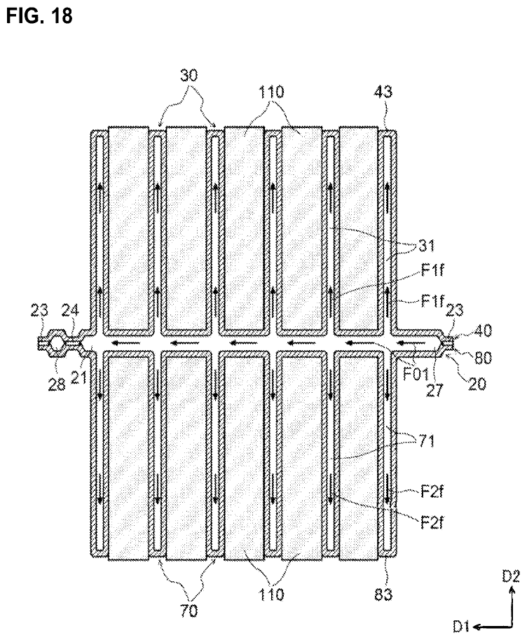

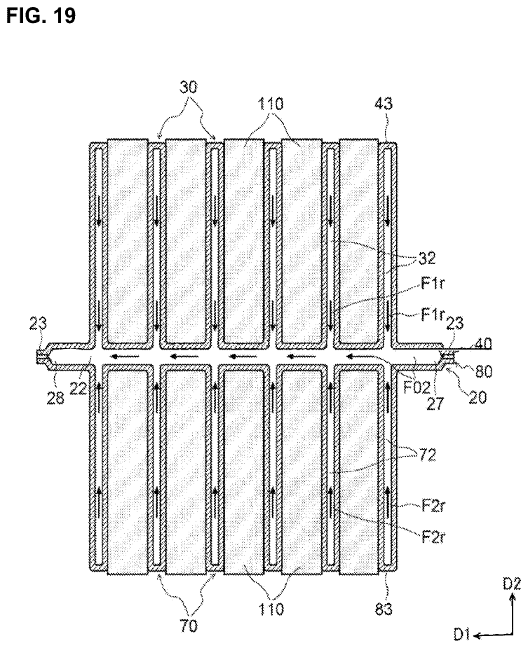

Next, operation of the heat exchanger 10 will be described. FIG. 18 is a sectional view illustrating a case where the power supply module 100 in FIG. 17 is cut along the line E-E. FIG. 19 is a sectional view illustrating a case where the power supply module 100 in FIG. 17 is cut along the line F-F. The operation of the first heat exchanging bodies 30 is the same as in the above-described embodiment, and its description is thus omitted.

The medium introduced into the first base channel 21 of the base part 20 via the introducing member 61 and the inlet portion 27 flows toward the outlet portion 28 in the first direction D1. As illustrated in FIG. 18, a plurality of the first forward channels 31 and a plurality of the second forward channels 71 are connected to the first base channel 21. Thus, the first base flow F01 diverges and flows into each of the first forward channels 31 and each of the second forward channels 71. The medium flowing into the second forward channel 71 flows toward the folded portion 83 in the second direction D2. The medium flow along the second forward channel 71 is also referred to as a second forward flow F2f.

The second forward channel 71 is linked to the second return channel 72 in the vicinity of the folded portion 83. As illustrated in FIG. 19, the medium having reached the vicinity of the folded portion 83 flows along the second return channel 72 from the folded portion 83 toward the base part 20. The medium flow along the second return channel 72 is also referred to as a second return flow F2r.

As illustrated in FIG. 19, a plurality of the first return channels 32 and a plurality of the second return channels 72 are connected to the second base channel 22. The medium in each of the first return channels 32 and the medium in each of the second return channels 72 flow into the second base channel 22 and flow together. Then, the medium flows toward the outlet portion 28 in the first direction D1. The medium having reached the outlet portion 28 is discharged from the discharging member 62.

Next, a method of manufacturing the heat exchanger 10 and the power supply module 100 will be described.

First, as illustrated in FIG. 10, the first heat exchanging bodies 30 are formed in the single first film 40. Similarly, the second heat exchanging bodies 70 are formed in the single second film 80.

Then, the reinforcing structure 50 is prepared. The reinforcing structure 50 includes the base reinforcing member 55 extending in the first direction D1, the first reinforcing members 51 aligned in the first direction D1 and connected to the base reinforcing member 55, and the second reinforcing members 52 aligned in the first direction D1 and connected to the base reinforcing member 55 on a side opposite to a side having the first reinforcing members 51. Then, the first reinforcing members 51 are inserted into the first non-joint portions 35 of the respective first heat exchanging bodies 30. Furthermore, the second reinforcing members are inserted into the second non-joint portions 75 of the respective second heat exchanging bodies 70.

Then, the second film 80 expanding in the first direction D1 is overlaid on a portion, expanding in the first direction D1, of the first film 40. Then, the base joining process of partially joining the inner surface of the first film 40 to the inner surface of the second film 80 is performed. This forms the base outer edge joint portion 23 and the base section joint portion 24 between the first film 40 and the second film 80. In this way, the heat exchanger 10 including the base part 20, the first heat exchanging bodies 30, and the second heat exchanging bodies 70 is manufactured.

Then, as illustrated in FIG. 15, the heat exchanger 10 and the battery cells 110 are combined. This manufactures the power supply module 100 illustrated in FIG. 17.

According to this embodiment, the first heat exchanging bodies 30 are composed of the single first film 40, and the second heat exchanging bodies 70 are composed of the single second film 80. Furthermore, the base part 20 is composed of a portion of the first film 40 and a portion of the second film 80. Thus, the first forward channels 31 of the first heat exchanging bodies 30 are naturally connected to the first base channel 21 of the base part 20. Similarly, the first return channels 32 of the first heat exchanging bodies 30 are naturally connected to the second base channel 22 of the base part 20. Similarly, the second forward channels 71 of the second heat exchanging bodies 70 are naturally connected to the first base channel 21 of the base part 20. Similarly, the second return channels 72 of the second heat exchanging bodies 70 are naturally connected to the second base channel 22 of the base part 20. Thus, components, such as joint pipes, are unnecessary, which can reduce the number of components of the heat exchanger 10. Furthermore, a process of attaching joint pipes and the like is unnecessary, which can reduce processes required to manufacture the heat exchanger 10. Thus, the manufacturing cost of the heat exchanger 10 can be reduced. Furthermore, by forming the second heat exchanging bodies 70 in the second film 80, the number of the battery cells 110 included in the power supply module 100 can be increased.

### Second Modification

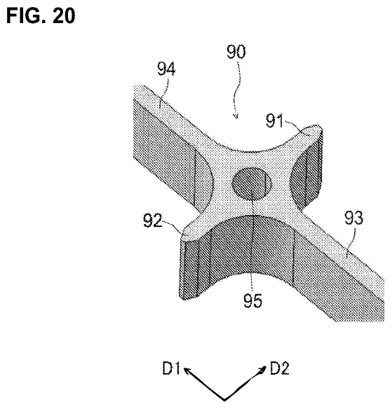

In a position where three or more joint portions intersect, a spacer may be inserted. FIG. 20 is a diagram illustrating an example spacer 90. The spacer 90 in FIG. 20 has a cross shape. For example, the spacer 90 includes a first portion 91, a second portion 92, a third portion 93, and a fourth portion 94 that extend outward from a central portion 95. In the central portion 95, a hole penetrating the spacer 90 may be formed.

The first portion 91 is connected to, for example, the first outer edge joint portion 33 of the first heat exchanging body 30. The second portion 92 is connected to, for example, the second outer edge joint portion 73 of the second heat exchanging body 70. The third portion 93 is connected to, for example, the base outer edge joint portion 23 positioned upstream of the first portion 91 in the first direction D1. The fourth portion 94 is connected to, for example, the base outer edge joint portion 23 positioned downstream of the first portion 91 in the first direction D1. By providing the spacer 90, occurrence of a gap between the joint portions can be restrained.

### REFERENCE SIGNS LIST

10 Heat exchanger
20 Base part
21 First base channel
22 Second base channel
23 Base outer edge joint portion
24 Base section joint portion
25 Base non-joint portion
27 Inlet portion
28 Outlet portion
30 First heat exchanging body
31 First forward channel
32 First return channel
33 First outer edge joint portion
34 First section joint portion
35 First non-joint portion
40 First film
43 Folded portion
50 Reinforcing structure
51 First reinforcing member
52 Second reinforcing member
55 Base reinforcing member
61 Introducing member
62 Discharging member
70 Second heat exchanging body
71 Second forward channel
72 Second return channel
73 Second outer edge joint portion
74 Second section joint portion
75 Second non-joint portion
80 Second film
83 Folded portion
90 Spacer

1. A heat exchanger configured to exchange heat with a plurality of target members aligned in a first direction, the heat exchanger comprising:
a base part including a first base channel and a second base channel along which a medium flows in the first direction; and
a plurality of first heat exchanging bodies connected to the base part and aligned in the first direction, each of the first heat exchanging bodies being positioned between two of the target members and including a first channel through which the medium circulates in a second direction intersecting the first direction,
the first heat exchanging bodies each including a front portion and a back portion configured by folding a first film, a first outer edge joint portion joining inner surfaces of the first film along outer edges of the front portion and the back portion, and a first section joint portion joining inner surfaces of the first film so as to divide the first channel into a first forward channel connected to the first base channel and a first return channel connected to the second base channel,
the base part including the first film.

2. The heat exchanger according to claim 1, wherein the base part includes an inlet portion positioned at a first end in the first direction and supplying the medium to the first base channel and an outlet portion positioned on a side opposite to the first end in the first direction and discharging the medium from the second base channel.

3. The heat exchanger according to claim 1, comprising a first reinforcing member inserted between the front portion and the back portion of the first heat exchanging body and surrounded by the first section joint portion.

4. The heat exchanger according to claim 3, comprising a reinforcing structure including a base reinforcing member positioned between the first base channel and the second base channel and a plurality of the first reinforcing members connected to the base reinforcing member and surrounded by the first section joint portions.

5. The heat exchanger according to claim 1, wherein the base part includes a second film including an inner surface facing the inner surface of the first film and a base section joint portion positioned between the first base channel and the second base channel and joining the inner surface of the first film to the inner surface of the second film.

6. The heat exchanger according to claim 5, wherein the second film expands flat in a position where the first section joint portions are connected to the base section joint portion.

7. The heat exchanger according to claim 5, comprising a plurality of second heat exchanging bodies connected to the base part and aligned in the first direction, each of the second heat exchanging bodies including a second channel through which the medium circulates in the second direction, wherein
the second heat exchanging bodies each include a front portion and a back portion configured by folding a second film, a second outer edge joint portion joining inner surfaces of the second film along outer edges of the front portion and the back portion, and a second section joint portion joining inner surfaces of the second film so as to divide the second channel into a second forward channel connected to the first base channel and a second return channel connected to the second base channel.
